(19) United States
(12) Patent Application Publication
(10) Pub. No.: US 2005/0254326 A1
(43) Pub. Date: Nov. 17, 2005

(54) Semiconductor integrated circuit for reducing crosstalk and method for designing the same

(76) Inventor: Takeshi Kitahara, Kawasaki-shi (JP)

Correspondence Address: DLA PIPER RUDNICK GRAY CARY US, LLP, 2000 UNIVERSITY AVENUE, E. PALO ALTO, CA, 94303-2248, US

(21) Appl. No.: 11/127,839

(22) Filed: May 12, 2005

(30) Foreign Application Priority Data
May 13, 2004 (JP) P2004-143921

(51) Int. Cl. G11C 7/00

(52) U.S. Cl. 365/218

(57) ABSTRACT

A semiconductor integrated circuit includes a logic circuit, a first switching cell connecting a first power supply line with a first virtual power line so as to drive the logic circuit, and a second switching cell connecting a second power supply line with a second virtual power line so as to drive the logic circuit. A time constant defined by the product of resistance and capacitance, which are measured between the first virtual power line and the first power supply line, is held to a constant value.

### CROSS REFERENCE TO RELATED APPLICATIONS AND INCORPORATION BY REFERENCE

This application is based upon and claims the benefit of priority from prior Japanese Patent Application P2004-143921 filed on May 13, 2004; the entire contents of which are incorporated by reference herein.

### BACKGROUND OF THE INVENTION

1. Field of the Invention

The present invention relates to a semiconductor integrated circuit and a design method for the same, particularly to a semiconductor integrated circuit having virtual power lines and a design method for the same.

2. Description of the Related Art

An earlier technology for a semiconductor device includes virtual power lines v-Vdd and v-Vss as power supply lines used to drive a combinational logic circuit and nonvolatile latch circuits. The virtual power lines v-Vdd and v-Vss are connected to power supply lines Vdd and Vss via MOS field effect transistors (MOSFETs), each having a high threshold voltage. While the semiconductor device is normally operating, the high threshold voltage MOSFETs are turned on, and the potential of the virtual power lines v-Vdd and v-Vss are almost the same as power supply lines Vdd and Vss.

On the other hand, while the semiconductor device is in a wait state, the high threshold voltage MOSFETs are turned off, resulting in interruption of power supplies from Vdd to v-Vdd and also from Vss to v-Vss to save power consumption during the wait state.

However, the potential of the virtual power line v-Vss increases due to crosstalk attributable to the signal transition of an adjacent signal wiring. The potential increase of the virtual power line v-Vss increases a propagation delay time when the signal of the combinational logic circuit goes to a logic value ‘1’ from ‘0’. Even with the virtual power line v-Vdd, crosstalk attributable to the signal transition of an adjacent signal wiring increases a propagation delay time of an output signal changing from logic value ‘0’ up to ‘1’.

### SUMMARY OF THE INVENTION

An aspect of the present invention inheres in a semiconductor integrated circuit comprising a logic circuit; a first switching cell configured to connect a first power supply line with a first virtual power line positioned on the first power supply line side so as to drive the logic circuit; and a second switching cell configured to connect a second power supply line with a second virtual power line positioned on the second power supply line side so as to drive the logic circuit. A time constant defined by the product of resistance and capacitance, which are measured between the first virtual power line and the first power supply line, is held to a constant value.

Another aspect of the present invention inheres in a computer implemented method for designing a semiconductor integrated circuit, including changing a signal level of an aggressing signal line adjacent to a virtual power line and extending along the virtual power line, and analyzing crosstalk along the virtual power line; selecting the virtual power line and a transistor connected between the virtual power line and a power supply line when it is determined, based on the crosstalk analysis results, that crosstalk influences an operation of the semiconductor integrated circuit; and correcting the semiconductor integrated circuit based on information of the virtual power line and the transistor.

Still another aspect of the present invention inheres in a computer implemented method for designing a semiconductor integrated circuit, including setting a maximum length constraint of a virtual power line driving a plurality of logic circuits and a plurality of sequential circuits; placing the plurality of logic circuits and the plurality of sequential circuits in a cell array region set based on the maximum length constraint of the virtual power line; generating a clock net for the plurality of sequential circuits; and routing signal wirings to connect the plurality of logic circuits and the plurality of sequential circuits to one another, and the virtual power line connects the plurality of logic circuits and the plurality of sequential circuits, in the cell array region.

### BRIEF DESCRIPTION OF DRAWINGS

FIG. 1 is a block diagram showing a semiconductor integrated circuit according to a first embodiment of the present invention;

FIG. 2 is a schematic view showing a circuit configuration according to the first embodiment of the present invention;

FIG. 3 is a schematic view showing an exemplary circuit configuration to be corrected by using a semiconductor integrated circuit design system according to the first embodiment of the present invention;

FIG. 4 is a schematic view showing a circuit configuration to explain an exemplary circuit correcting method using a semiconductor integrated circuit design system according to the first embodiment of the present invention;

FIG. 5 is a schematic view showing a circuit configuration to explain another exemplary circuit correcting method using a semiconductor integrated circuit design system according to the first embodiment of the present invention;

FIG. 6 is a schematic view showing a circuit configuration to explain still another exemplary circuit correcting method using a semiconductor integrated circuit design system according to the first embodiment of the present invention;

FIG. 7 is a schematic view showing a circuit configuration according to the first embodiment of the present invention;

FIG. 8 is a schematic view showing a portion of the circuit configuration shown in FIG. 7;

FIG. 9 is a schematic view showing a circuit configuration according to the first embodiment of the present invention;

FIG. 10 is a block diagram showing the semiconductor integrated circuit design system according to the first embodiment of the present invention;

FIG. 11 is a flowchart explaining an operation of the semiconductor integrated circuit design system according to the first embodiment of the present invention;

FIG. 12 is a schematic view showing a delay time of a circuit, which is corrected by using the semiconductor integrated circuit design system according to the first embodiment of the present invention;

FIG. 13 is a block diagram showing a semiconductor integrated circuit design system according to a second embodiment of the present invention;

FIG. 14 is a flowchart explaining an operation of the semiconductor integrated circuit design system according to the second embodiment of the present invention;

FIG. 15A is a plane view showing a circuit placed in a cell array region, which is used for a semiconductor integrated circuit design system according to the second embodiment of the present invention;

FIG. 15B is a block diagram showing a circuit placed in a cell array region, which is used for the semiconductor integrated circuit design system according to the second embodiment of the present invention;

FIG. 16 is a flowchart explaining an operation of the semiconductor integrated circuit design system according to the second embodiment of the present invention;

FIG. 17 is a schematic view showing a cross section of a semiconductor integrated circuit designed by using the semiconductor integrated circuit design system according to the second embodiment of the present invention;

FIG. 18 is a schematic view showing a plane view of the semiconductor integrated circuit designed by using the semiconductor integrated circuit design system according to the second embodiment of the present invention;

FIG. 19 is a block diagram showing a semiconductor integrated circuit design system according to a third embodiment of the present invention;

FIG. 20 is a plane view showing routes of wirings corrected by using the semiconductor integrated circuit design system according to the third embodiment of the present invention;

FIG. 21 is a plane view showing the routes of wirings in FIG. 20, which is corrected by using the semiconductor integrated circuit design system according to the third embodiment of the present invention;

FIG. 22 is a flowchart explaining an operation of the semiconductor integrated circuit design system according to the third embodiment of the present invention;

FIG. 23 is a schematic view showing a circuit configuration as an exemplary circuit used for an embodiment of the present invention; and

FIG. 24 shows a circuit, which is used to explain a method for correcting the circuit of FIG. 23 using the semiconductor integrated circuit design system according to the first embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified. In the following descriptions, numerous specific details are set fourth such as specific signal values, etc. to provide a thorough understanding of the present invention. However, it will be obvious to those skilled in the art that the present invention may be practiced without such specific details.

### First Embodiment

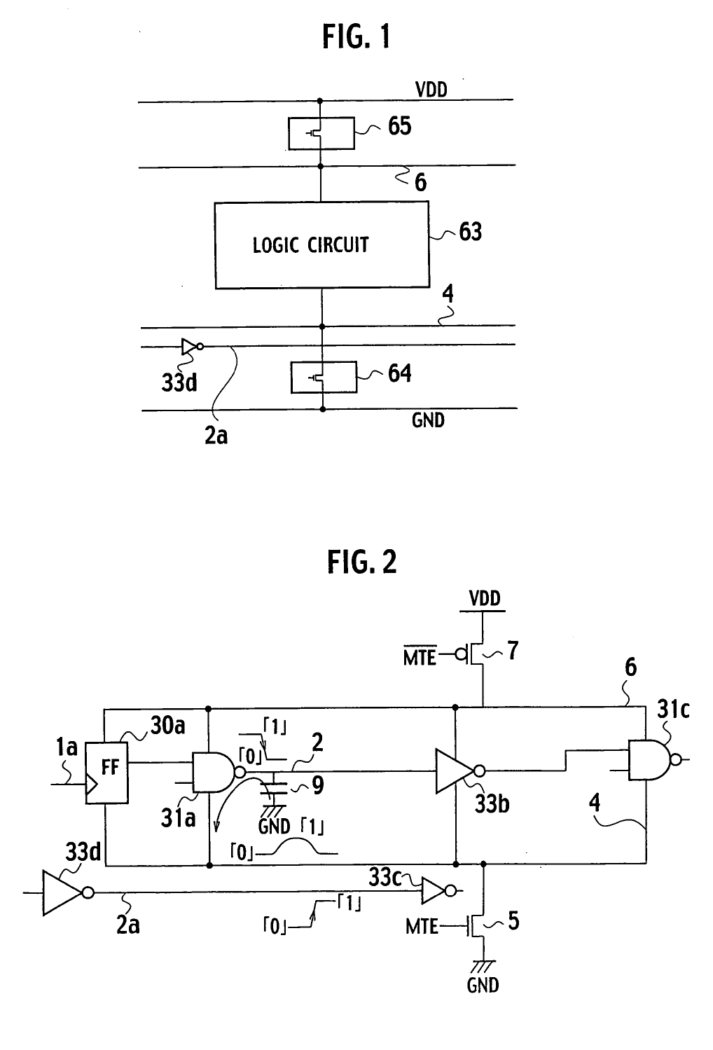

As shown in FIG. 1, a semiconductor integrated circuit, according to a first embodiment of the present invention, includes a logic circuit 63 comprising transistors having a low threshold voltage, a first switching cell 64, which connects a first power supply line (GND) and a first virtual power line 4 positioned on the first power supply line side, and a second switching cell 65, which connects a second power supply line (VDD) and a second virtual power line 6 positioned on the second power supply line side. The first virtual power line 4 and the second virtual power line 6 are used to drive the logic circuit 63. The first switching cell 64 includes a metal insulator semiconductor (MIS) transistor having a high threshold voltage. The second switching cell 65 includes a MIS transistor having a high threshold voltage. A time constant, which depends on the product of the resistance between the first virtual power line 4 and the first power supply line (GND) times the capacitance therebetween, is held to a constant value. In the following description, the time constant depending on the product of the resistance between the first virtual power line 4 and the first power supply line (GND) times the capacitance therebetween is referred to as the ‘first time constant’.

When the semiconductor integrated circuit is normally operating, the first switching cell 64 and the second switching cell 65 are in a conductive state. At this time, the potential of the first virtual power line 4 is GND while the potential of the second virtual power line 6 is almost equal to VDD, so as to allow the logic circuit 63 to operate at a high speed.

When the semiconductor integrated circuit is in a wait state, the first switching cell 64 and the second switching cell 65 are in a non-conductive state. At this time, the power supply to the first virtual power line 4 from the first power supply line, and to the second virtual power line 6 from the second power supply line is interrupted. This reduces power consumption during the wait state.

The length of the first virtual power line 4 is designed to be constant, so that the first time constant can be fixed. The length of the first virtual power line 4 is designed to a constant less than 100 μm, for example.

Even when a signal level of an aggressing signal wiring 2a, which is routed next to and extends along the first virtual power line 4, changes and crosstalk occurs due to capacitive coupling between the aggressing signal wiring 2a and the first virtual power line 4, the first time constant is held to a constant value. Accordingly, when the potential of the first virtual power line 4 increases, it will return to the same potential as that of the first power supply line. This operation prevents a signal delay of the logic circuit 63 due to a potential change of the first virtual power line 4. Therefore, the length of the first virtual power line 4 is set to a value that prevents a potential change of the first virtual power line 4, due to crosstalk, from adversely influencing the circuit operation. The length of the first virtual power line 4 is set, based on, for example, an increase in signal delay due to the potential change of the first virtual power line 4. If a signal delay is due to a 10% change in potential of the first virtual power line 4 cannot be accommodated, the first time constant is determined such that the potential change of the first virtual power line 4 can be 10% or less. The length of the first virtual power line 4 is set so that the first time constant satisfies the above requirements.

FIG. 2 shows an exemplary semiconductor integrated circuit including the first switching cell 64 shown in FIG. 1, according to the first embodiment.

The circuit in FIG. 2 includes a p-channel MIS transistor 7 connected to the second power supply line, a second virtual power line 6 connected to the MIS transistor 7, an n-channel MIS transistor 5 connected to the first power supply line, a first virtual power line 4 connected to the MIS transistor 5, a sequential circuit (flip-flop) 30a connected between the first virtual power line 4 and the second virtual power line 6, a NAND circuit 31a, which receives an output from the sequential circuit 30a, a NOT circuit 33b, which receives an output from the NAND circuit 31a, a NAND circuit 31c, which receives an output from the NOT circuit 33b, a NOT circuit 33d adjacent to the first virtual power line 4, and a NOT circuit 33c, which receives an output from the NOT circuit 33d via an aggressing signal wiring 2a. Circuits other than the MIS transistors 5 and 7 include low threshold voltage transistors so as to improve the operating speed.

The MIS transistors 5 and 7 have high threshold voltage so as to decrease leakage current during a wait state. The first virtual power line 4 is routed adjacent to and in parallel with the aggressing signal wiring 2a. Since there is a large amount of coupling capacitance between the aggressing signal wiring 2a and the first virtual power line 4, the change of the signal level of the aggressing signal wiring 2a changes a signal delay of the NAND circuit 31a connected to the first virtual power line 4.

Analysis of crosstalk can be generally carried out using a transistor level simulator or static timing analyzer; however, use of the simulator is limited due to computer capability and performance. This limitation may be due to several thousands of transistors and several hundred thousands of coupling capacitors included in a critical path netlist, for example. If such a netlist with a large number of components is analyzed by the simulator, calculation regarding a mere single input vector under a single operating condition takes several days.

Moreover, a timing analysis must be carried out under a variety of operating conditions. So, simulation by a simulator using design data for several million gates is not realistic.

According to the first embodiment, the aggressing signal wiring 2a extending along and adjacent to the first virtual power line 4 is detected, circuit data relevant to the first virtual power line 4 is extracted, and crosstalk in the semiconductor integrated circuit is then analyzed.

Circuit data for the MIS transistor 5, the first virtual power line 4, the sequential circuit 30a, the NAND circuit 31a, the NOT circuit 33b, the NAND circuit 31c, the MIS transistor 7, the second virtual power line 6, the aggressing signal wiring 2a, a wiring capacitance 9, the NOT circuit 33d, the NOT circuit 33c, the first power supply line, and the second power supply line is extracted to integrate a semiconductor integrated circuit.

Crosstalk due to the first virtual power line 4 will occur under the following conditions. To begin with, the MIS transistors 5 and 7 are turned on moving to a conductive state, and thus the sequential circuit 30a, the NAND circuits 31a and 31c, and the NOT circuits 33b, 33c, and 33d move to an operating state. The output signal from the NAND circuits 31a is changed from ‘1’ to ‘0’, and then the output signal of the NOT circuit 33d changes from ‘0’ to ‘1’. As a result, changes in the potential of the aggressing signal wiring 2a influence the potential of the first virtual power line 4 to slightly increase from a signal level of a logical level ‘0’; namely, crosstalk occurs.

When crosstalk occurs on the first virtual power line 4, carriers accumulated in the wiring capacitance 9 between the signal wiring 2 and GND flow through the signal wiring 2 and then the NAND circuit 31a to the first virtual power line 4 at the time when the output signal of the NAND circuit 31a begins to change from ‘1’ to ‘0’. The falling delay time of the output signal of the NAND circuit 31a is prolonged during the time when carriers accumulated in the wiring capacitance 9 are flowing to the first virtual power line 4, resulting in a drop in the operating speed.

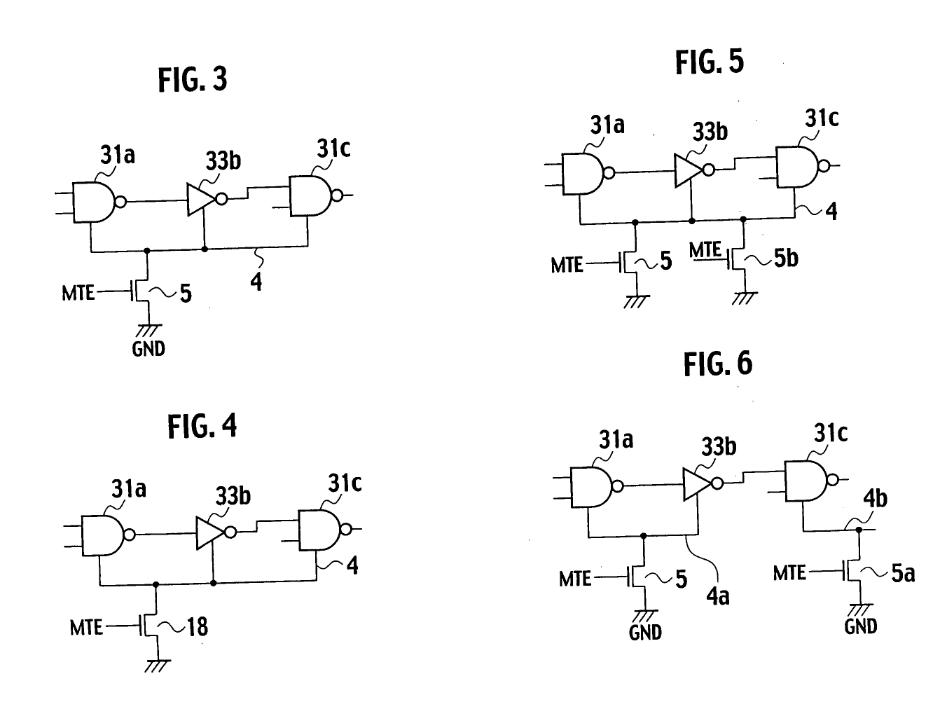

Analysis of crosstalk that causes degradation in the falling delay time of the output signal from the NAND circuit 31a shows that the propagation delay time of the signal from the NAND circuit 31a is 10% or greater. An exemplary method for changing the first time constant so as to control propagation delay time of the signal, which increases due to crosstalk along the first virtual power line 4, is described using FIGS. 3 to 6.

FIG. 3 shows an exemplary circuit that causes the aforementioned crosstalk and that includes a virtual power line region including the first virtual power line 4, which is commonly connected to the NAND circuit 31a, the NOT circuit 33b, the NAND circuit 31c, and the MIS transistor 5.

A semiconductor integrated circuit in FIG. 4 is an exemplary circuit correction, which is provided by increasing the gate width of the MIS transistor 5 without changing the placement of the NAND circuit 31a, the NOT circuit 33b, and the NAND circuit 31c, and the first virtual power line 4 shown in FIG. 3, so as to form a second MIS transistor 18 (n-channel transistor) with a low conductive resistance. The second MIS transistor 18 causes an increase in cell area relative to the MIS transistor 5; however, it decreases or suppresses crosstalk.

A semiconductor integrated circuit in FIG. 5 is an exemplary circuit correction, which is provided by connecting a MIS transistor 5b having the same cell area, operating speed, and threshold voltage as those of the MIS transistor 5 between the first virtual power line 4 and the first power supply line without changing the placement of the NAND circuit 31a, the NOT circuit 33b, the NAND circuit 31c, and the first virtual power line 4 shown in FIG. 3. Since the MIS transistor 5b is connected to the midpoint of the first virtual power line 4 that connects the NOT circuit 33b with the NAND circuit 31c, an increase in the potential of the first virtual power line 4 due to crosstalk effectively decreases. The cell area increases by the area of the MIS transistor 5b; however, crosstalk can be effectively decreased or suppressed.

A semiconductor integrated circuit in FIG. 6 is an exemplary circuit correction, which is provided by dividing the first virtual power line 4 into first virtual power lines 4a and 4b without changing the placement of the NAND circuit 31a, the NOT circuit 33b, and the NAND circuit 31c shown in FIG. 3. The first virtual power line 4a is connected to the NAND circuit 31a, the NOT circuit 33b, and the MIS transistor 5. Turning on the MIS transistor 5 electrically connects the first virtual power line 4a and the first power supply line (GND). The first virtual power line 4b is connected to the NAND circuit 31c and the MIS transistor 5a. Turning on the MIS transistor 5a in sync with the MIS transistor 5 electrically connects the first virtual power line 4b and the first power supply line (GND).

The first virtual power line 4a has a shorter length than that of the first virtual power line 4. Therefore, crosstalk can be effectively decreased or suppressed. The first virtual power line 4b supplies majority carriers to the NAND circuit 31c via the MIS transistor 5a, which operates in sync with the MIS transistor 5.

While the example of dividing the first virtual power line 4 into the first virtual power lines 4a and 4b is shown in FIG. 6, the first virtual power line 4 may be alternatively divided into three or more wirings.

According to an exemplary semiconductor integrated circuit of the first embodiment, the exemplary circuit corrections shown in FIGS. 4 to 6 may be used.

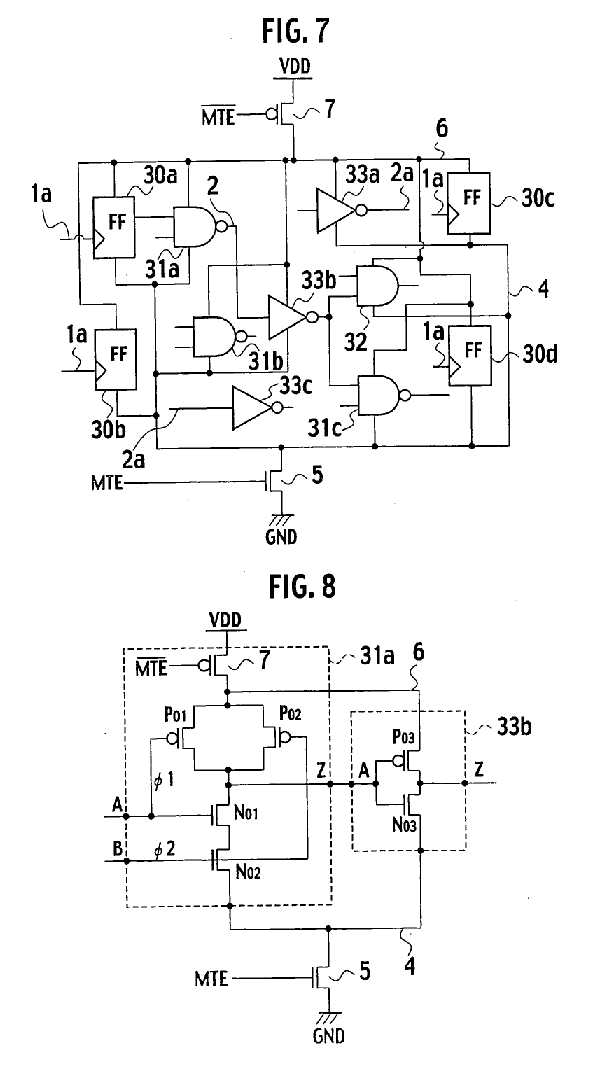

As shown in FIG. 7, a MIS transistor 5 (n-channel transistor) positioned on the first power supply side is connected between the first power supply line (GND) and the first virtual power line 4. The MIS transistor 5 has a high threshold voltage so as to decrease leakage current during a wait state.

A MIS transistor 7 (p-channel transistor) is connected between the second power supply line (VDD) and the second virtual power line 6. The MIS transistor 7 has a high threshold voltage so as to decrease leakage current during a wait state.

Sequential circuits 30a to 30d, NAND circuits 31a to 31c, an AND circuit 32, and NOT circuits 33a, 33b, and 33c are placed and connected between the first virtual power line 4 and the second virtual power line 6. The NOT circuit 33c is placed near the NAND circuit 31b. Each of the logic gates and sequential circuits includes transistors, each having a low threshold voltage so as to improve the operating speed.

A clock signal is provided to the sequential circuits 30a to 30d via a clock signal wiring 1a. In FIG. 7, the output terminal of the NAND circuit 31a is connected to the input terminal of the NOT circuit 33b via a signal wiring 2; alternatively, other logic circuits and sequential circuits may be connected via the signal wiring 2.

As shown in FIG. 7, in the first virtual power line 4, a segment between the MIS transistor 5 and the NOT circuit 33a is the longest while a segment between the MIS transistor 5 and the NAND circuit 31a is the second longest. Also, in the first virtual power line 4, there are segments running along signal wirings and segments running in a direction perpendicular to those signal wirings.

In the second virtual power line 6, a segment between the MIS transistor 7 and the NAND circuit 31c is the longest while a segment between the MIS transistor 7 and the sequential circuit 30b is the second longest.

In other words, both of the first virtual power line 4 and the second virtual power line 6 tend to become longer. The aggressing signal wiring 2a connected to the input stage of the NOT circuit 33c, is adjacent to a part of the first virtual power line 4 and extends along the first virtual power line 4. Moreover, the aggressing signal wiring 2a connected to the output stage of the NOT circuit 33a, is adjacent to a part of the second virtual power line 6 and extends along the second virtual power line 6.

Upon reception of a signal MTE of ‘1’ while logic circuits and sequential circuits are operating, the MIS transistor 5 becomes conductive; upon reception of a signal MTE of ‘0’ while those logic circuits and sequential circuits are in a wait state, the MIS transistor 5 moves to an interrupt state.

Upon reception of an inverted signal ‘0’ to the signal MTE while logic circuits and sequential circuits are operating, the MIS transistor 7 becomes conductive; upon reception of an inverted signal ‘1’ to the signal MTE while those logic circuits and sequential circuits are in a wait state, the MIS transistor 7 moves to an interrupt state.

In the first virtual power line 4 and the second virtual power line 6, crosstalk may occur under the following conditions. To begin with, the MIS transistors 5 and 7 are turned on to become conductive, so that the NAND circuits 31a to 31c, the AND circuit 32, and the NOT circuits 33a to 33c are in an operating state. Afterwards, a switching is propagated from the logic circuit NAND 31a to the signal wiring 2 while the signal level of the aggressing signal wiring 2a, which is adjacent to and extends along the first virtual power line 4, and is connected to the input terminal of the NOT circuit 33c, changes from ‘0’ to ‘1’. Consequently, crosstalk occurs along the first virtual power line 4, resulting in an increase in the potential of the first virtual power line 4.

In the same manner, crosstalk occurs at the time when the signal level of the aggressing signal wiring 2a changes from ‘1’ to ‘0’; wherein the aggressing signal wiring 2a extends along and adjacent to the second virtual power line 6 and is connected to the output terminal of the NOT circuit 33a.

FIG. 8 shows an exemplary detailed circuit of the NAND circuit 31a and the NOT circuit 33b of FIG. 7. As shown in FIG. 8, the NAND circuit 31a is implemented as a dynamic NAND circuit having two input terminals A and B, by arranging two p-channel transistors P01 and P02 connected in parallel between the n-channel MIS transistor 5 and the p-channel MIS transistor 7 and inserting two n-channel transistors N01 and N02 connected in series on the MIS transistor 5 side.

The NOT circuit 33b is implemented by serially connecting a p-channel transistor P03 connected to the MIS transistor 7 and an n-channel transistor N03 connected to the MIS transistor 5. The NOT circuit 33b is an inverter having a node as an input terminal A commonly connected to the gates of the p-channel transistor P03 and the n-channel transistor N03, and a node as an output terminal Z connecting the p-channel transistor P03 and the n-channel transistor N03.

The MIS transistors 5 and 7 have respective high threshold voltages. The NAND circuit 31a and the NOT circuit 33b include the p-channel transistors P01, P02, and P03 and the n-channel transistors N01, N02, and N03 with respective low threshold voltages. Therefore, a dynamic logic circuit can be implemented by a multi-threshold complementary MOS (CMOS) circuit, which allows only a minimal drop in speed and decrease in subthreshold leakage current.

As described above, each of the first and second virtual power lines 4 and 6 shown in FIG. 8 tends to be longer than a wiring connecting the output terminal Z and the input terminal A.

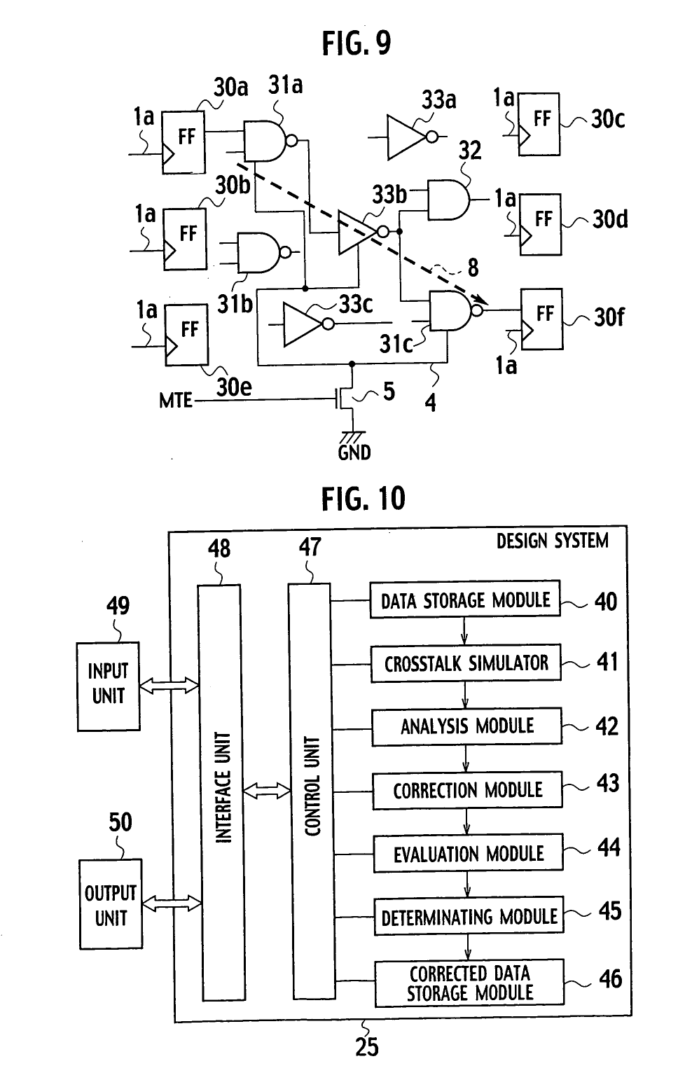

The circuit corrections shown in FIGS. 4 to 6 may be used for an exemplary semiconductor integrated circuit shown in FIG. 9. The exemplary semiconductor integrated circuit shown in FIG. 9 includes NAND circuits 31a, 31b, and 31c placed between an input stage of sequential circuits 30a, 30b, and 30e and an output stage of sequential circuits 30c, 30d, and 30f, and an AND circuit 32 and NOT circuits 33a, 33b, and 33c. Moreover, the exemplary circuit in FIG. 9 further includes the MIS transistor 5 connected to the first power supply line and having a gate which receives a signal MTE, and the first virtual power line 4, which supplies majority carriers via the MIS transistor 5 from the first power supply line.

The first virtual power line 4 is connected to the NAND circuits 31a and 31c and the NOT circuit 33b. Each of the NAND circuits 31a and 31c and the NOT circuit 33b includes transistors having a low threshold voltage while other logic circuits and sequential circuits include transistors having a high threshold voltage. The MIS transistor 5 is a high threshold voltage MIS transistor.

In the exemplary circuit shown in FIG. 9, a clock signal is provided to the sequential circuits 30a to 30f via a clock signal wiring 1a. The sequential circuits 30a to 30f load data signals in sync with the clock signal.

For example, the output signal from the sequential circuit 30a is provided to the NAND circuit 31a; the output signal from the NAND circuit 31a is provided to the NOT circuit 33b; the output signal from the NOT circuit 33b is provided to the NAND circuit 31c; and the output signal from the NAND circuit 31c is provided to the sequential circuit 30f. The sequential circuit 30f loads the received signal as an output signal in sync with the next cycle of the clock signal.

The first virtual power line 4 extends to the NAND circuit 31a placed at the furthest end from the NAND circuit 31c. Therefore, crosstalk may occur on the first virtual power line 4 at the time when, for example, a signal provided to the NOT circuit 33c rises.

Such crosstalk causes degradation in the falling delay time of the output signals of the NAND circuit 31a, the NOT circuit 33b, and the NAND circuit 31c. As a result, propagation delay is prolonged for the critical path 8 due to crosstalk at three stages, and thus the circuit operating speed decreases considerably.

The semiconductor integrated circuit design system, according to a first embodiment of the present invention, is shown in FIG. 10. The design system 25 in FIG. 10 includes a data storage module 40, a crosstalk simulator 41, which generates crosstalk in a semiconductor integrated circuit, an analysis module 42, which analyzes crosstalk occurring in the semiconductor integrated circuit, and a correction module 43, which corrects the first virtual power line 4 based on the analysis results. The data storage module 40 stores semiconductor integrated circuit data for multiple MIS transistors, wiring capacitances, logic circuits, virtual power lines, and aggressing signal wirings.

Further, the design system 25 in FIG. 10 includes an evaluation module 44, which evaluates performance of the semiconductor integrated circuit having corrected wiring and transistors, a determinating module 45, which determines whether design of the semiconductor integrated circuit with a desired performance has been completed, and a corrected data storage module 46, which stores corrected circuit data corrected by the correction module 43.

A control unit 47 is connected to the data storage module 40, the crosstalk simulator 41, the analysis module 42, the correction module 43, the evaluation module 44, the determinating module 45, and the corrected data storage module 46, and provides electronic design automation (EDA).

The control unit 47 is further connected to an input unit 49 and an output unit 50 via an interface unit 48. The input unit 49 and the output unit 50 receive and provide design data, analysis data, circuit correction instructions, performance evaluation results, and corrected circuit data, respectively. The input unit 49 may include a keyboard, a mouse pointer, a numeric keypad, or a touch panel. The output unit 50 may include a display unit and/or a printer.

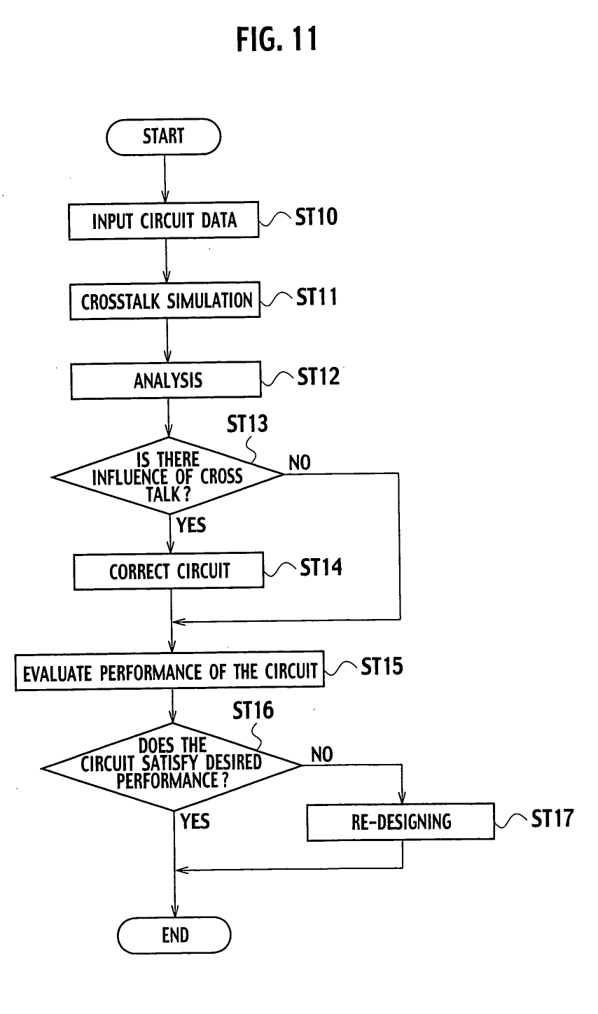

Referencing FIGS. 2 and 10 and a flowchart of FIG. 11, a semiconductor integrated circuit design method, according to the first embodiment, is described forthwith.

In step ST10 shown in FIG. 11, semiconductor integrated circuit data is provided to the design system 25 in FIG. 10. The received circuit data is then stored in the data storage module 40.

In step ST11, the crosstalk simulator 41 reads the circuit data stored in the data storage module 40, changes the signal level of the aggressing signal wiring 2a (see FIG. 2), which is routed adjacent to and extends along the first virtual power line 4, and carries out crosstalk simulation for the first virtual power line 4.

In step ST12, the analysis module 42 analyzes crosstalk and a potential of the first virtual power line 4, generating the analysis results.

In step ST13, the analysis module 42 determines, based on the crosstalk analysis results, whether or not there is an influence due to crosstalk. More specifically, when a change in the potential of the virtual power line exceeds an allowable threshold voltage, it is determined that there is a crosstalk influence. The ‘allowable threshold voltage’ is set such that the circuit can normally operate even if crosstalk occurs. The allowable threshold voltage is set based on a signal delay due to changes in the potential of the first virtual power line 4 in the semiconductor integrated circuit. If 10% of the change of the potential of the virtual power line 4 is the limit of what is permissible to a signal delay in the semiconductor integrated circuit, then the allowable threshold voltage is set to 10% of the potential of the virtual power line 4. In other words, in the case of an increase in the potential of the virtual power line 4 due to crosstalk is 10% or greater, it is determined that crosstalk is influencing the circuit operation. When it is determined that there is crosstalk influence on the circuit operation, the virtual power line 4 and the MIS transistor 5 connected thereto are selected as the circuit element to be corrected. Circuit data including information of the selected virtual power line 4 and MIS transistor 5 is sent to the correction module 43. When a potential increase ratio of the first virtual power line 4 is less than 10%, the analysis module 42 determines that there is no crosstalk influence on the circuit operation, and then transmits circuit data used by the crosstalk simulator 41 to the evaluation module 44.

In step ST14, the correction module 43 corrects a circuit based on the information of virtual power lines and transistors. As shown in FIG. 6, the virtual power line 4, for example, is divided into the first virtual power line 4a and the second virtual power line 4b. Alternatively, as shown in FIG. 4, the MIS transistor 5 may be changed to be the second MIS transistor 18 with a low conductive resistance. The gate width of the second MIS transistor 18 is wider than the gate width of the MIS transistor 5. Alternatively, as shown in FIG. 5, the MIS transistor 5b having the same cell area, operating speed, and threshold voltage as the MIS transistor 5 is connected between the first virtual power line 4 and the first power line. Alternatively, the first virtual power line 4 and the MIS transistor 5 may be corrected at the same time.

In step ST15, the evaluation module 44 evaluates circuits corrected to avoid crosstalk influence in step ST14. For example, electric characteristics and operating speed of circuits are evaluated by a simulator or a static timing analyzer.

In step ST16, the determinating module 45 determines whether the entire processing is completed based on the evaluation results provided from the evaluation module 44. More specifically, when the performances of the evaluated circuits have satisfied a desired performance, the design data for the semiconductor integrated circuit is stored in the corrected data storage module 46, and processing is then terminated. Otherwise, if the performances of the evaluated circuits have not satisfied a desired performance, the semiconductor integrated circuit is re-designed in step ST17 and processing is then terminated.

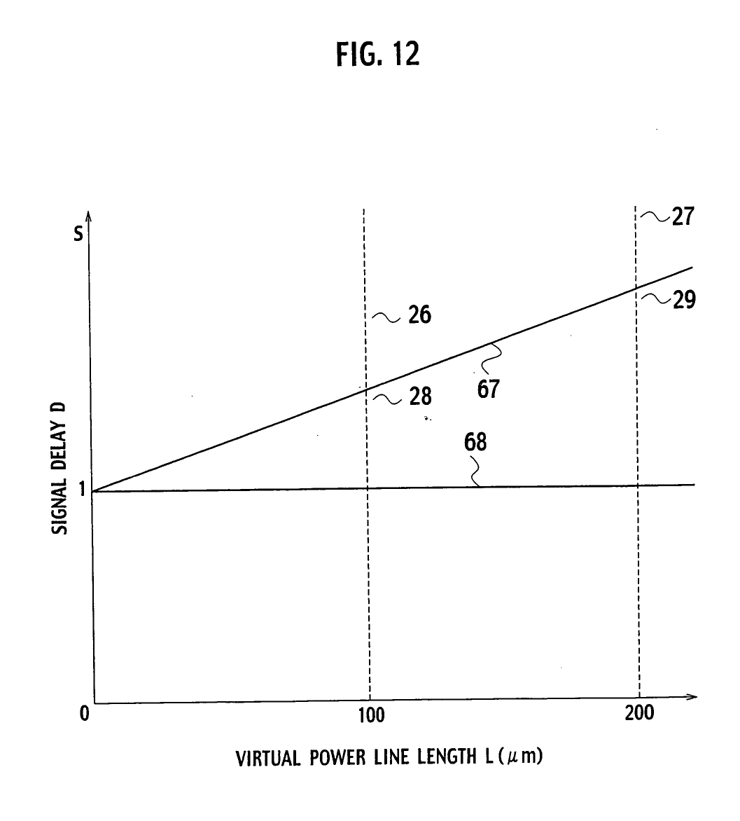

According to the semiconductor integrated circuit design method of the first embodiment, the first virtual power line 4 is divided into shorter segments, thereby improving a signal delay of the NAND circuit 31a. An exemplary improvement is shown in FIG. 12.

FIG. 12 is a graph showing the analysis results by the analysis module 42. The horizontal axis represents wiring length L while the vertical axis represents signal delay D of the NAND circuit 31a. The NAND circuit 31a using the first virtual power line 4 with a length of 200 μm has a signal delay D of 1.15 at a point 29 where a solid wiring 67 as the simulation results intersects with a dotted wiring 27. In other words, a signal delay D at the point 29 is 15% longer relative to an ideal signal delay 68 of the NAND circuit 31a, which does not increase even if the length of the first virtual power line 4 increases.

On the other hand, the first virtual power line 4 with a length of 100 μm has a signal delay D of 1.05 at the point 28 where the solid wiring 67 as the simulation results intersects with the dotted wiring 26. Increase in signal delay is 5% relative to the ideal value 68 of 1. However, an increase rate of the signal delay D at the point 28 is no greater than half of the increase rate of signal delay D at the point 29. In other words, the shorter the first virtual power line 4 is, the more effectively crosstalk can be prevented.

While the method for decreasing crosstalk influence along the first virtual power line 4 has been described, crosstalk influence along the second virtual power line 6 can be decreased in the same manner. More specifically, as shown in FIG. 7, the MIS transistor 7, which connects the second power line (VDD) and the second virtual power line 6, and the second virtual power line 6 are corrected in the same manner. For example, the second virtual power line 6 is divided into second virtual power lines 6a and 6b. Alternatively, the gate width of the MIS transistor 7 may be increased. Alternatively, a MIS transistor having the same cell area, operating speed, and threshold voltage as the MIS transistor 7 may be connected between the second virtual power line 6 and the second power line. Alternatively, the second virtual power line 6 and the MIS transistor 7 may be corrected at the same time. As a result, a time constant, which depends on the product of the resistance between the second virtual power line 6 and the second power line (VDD) times the capacitance therebetween, is held to a constant value.

Note that the logic circuit is not limited to a CMOS circuit including multi-threshold transistors, and may be a circuit including p-channel transistors or a circuit including n-channel transistors.

According to the embodiments of the present invention, crosstalk analysis is carried out after the layout of logic circuits and sequential circuits in a semiconductor integrated circuit having several million gates is designed and fixed. A signal delay of a logic circuit can be improved by merely correcting a virtual power line or a MIS transistor connected to the virtual power line. Consequently, circuit design is completed after one or several determinations, and earlier introduction of semiconductor devices in the market is possible.

### Second Embodiment

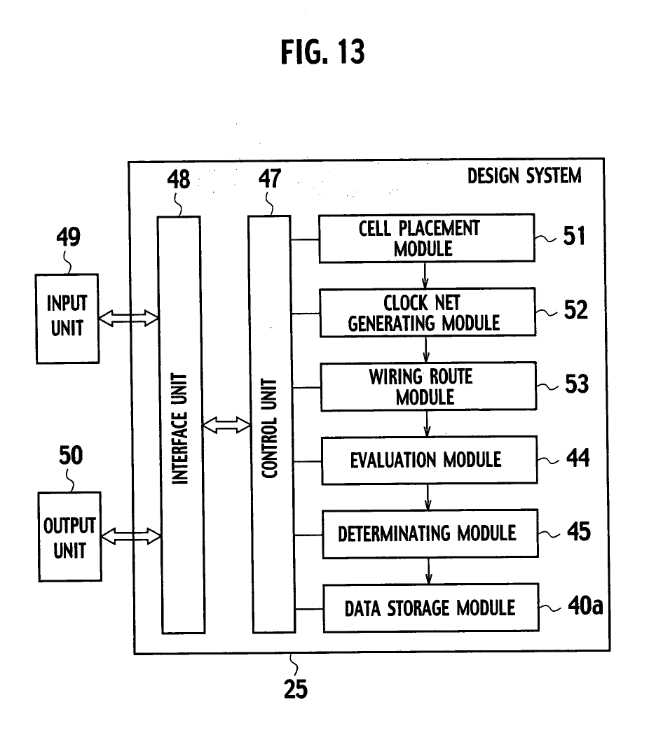

A semiconductor integrated circuit, according to the second embodiment of the present invention, is designed using the design system 25 shown in FIG. 13. The design system 25 in FIG. 13 includes a cell placement module 51, a clock net generating module 52, a wiring route module 53, and an evaluation module 44. The cell placement module 51 places multi-threshold cells in a cell array region. The clock net generating module 52 generates clock nets. The wiring route module 53 routes virtual power lines and signal wirings for sequential circuits in a cell array region. The evaluation module 44 evaluates electrical characteristics and operating speed based on circuit data for a semiconductor integrated circuit generated by the cell placement module 51, the clock net generating module 52, and the wiring route module 53. Since the determinating module 45, the data storage module 40a, the control unit 47, the interface unit 48, the input unit 49 and the output unit 50 have been described according to the first embodiment, description thereof is omitted.

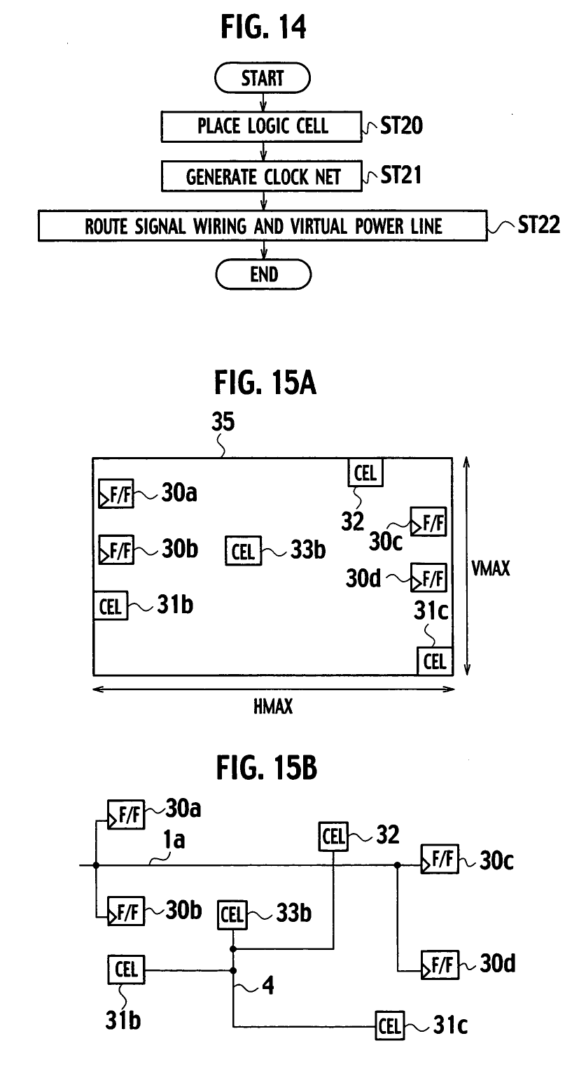

Referencing FIGS. 13, 15A, 15B, and a flowchart of FIG. 14, a semiconductor integrated circuit design method, according to the second embodiment, is explained forthwith.

In step ST20 of FIG. 14, the cell placement module 51 places sequential circuits 30a to 30d, which share the first virtual power line 4, NAND circuits 31b and 31c (referred to as ‘CEL’ in the drawing), a NOT circuit 33b (referred to as ‘CEL’ in the drawing), and an AND circuit 32 (referred to as ‘CEL’ in the drawing) in a cell array region 35 with a vertical length of VMAX and a horizontal length of HMAX as shown in FIG. 15A. The cell array region 35 is defined such that the sum of the vertical length of VMAX and the horizontal length of HMAX is no greater than the maximum length constraint of the first virtual power line 4. The ‘maximum length constraint of a virtual power line’ is set so that the semiconductor integrated circuit can normally operate. In other words, the maximum length constraint of the virtual power line is set based on an increase in a signal delay due to potential changes of the first virtual power line 4, which emanate from crosstalk. More specifically, the maximum length constraint of the virtual power line may be set based on a signal delay D increase rate of 10% due to crosstalk relative to a signal delay D of a logic circuit when no crosstalk occurs. Accordingly, when the wiring length is 100 μm and a signal delay D increase rate is 7%, a 100 μm long virtual power line is acceptable. As a result, crosstalk in the cell array region 35 does not influence the first virtual power line 4, which is shared by multiple logic circuits, or signal delay of a logic circuit does not increase.

In step ST21, the clock net generating module 52 generates a clock net 1a for the sequential circuits 30a to 30d placed in the cell array region 35 so that the delay time to each sequential circuit is the same, as shown in FIG. 15B.

In step ST22, the wiring route module 53 routes the first virtual power line 4 connected to the sequential circuits 30a to 30d, the NAND circuits 31b and 31c, the NOT circuit 33b, and the AND circuit 32. The wiring route module 53 further routes signal wirings, which connect the sequential circuits 30a to 30d, the NAND circuits 31b and 31c, the NOT circuit 33b, and the AND circuit 32 to one another, terminating the circuit placement and route processing.

According to the second embodiment, circuit placement and route is carried out under the constraint that the sum of the vertical length of VMAX and the horizontal length of HMAX is equal to the maximum length constraint of the first virtual power line 4. According to the semiconductor integrated circuit design method shown in the flowchart of FIG. 14, a long virtual power line causing crosstalk is avoided.

According to the semiconductor integrated circuit design method shown in the flowchart of FIG. 14, signal wirings and the first virtual power line 4 are routed after generating the clock net 1a. As a result, crosstalk further decreases, thereby improving the circuit operating speed.

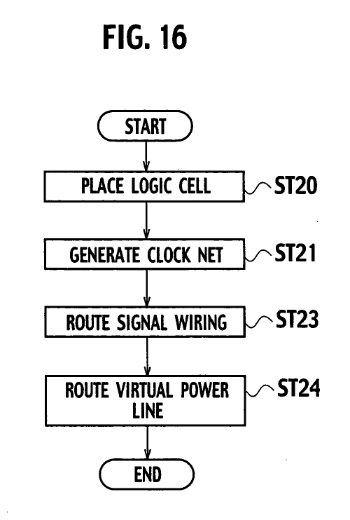

Referencing FIGS. 13, 15A, and 15B, and a flowchart of FIG. 16, a semiconductor integrated circuit design method, according to the second embodiment, is described forthwith.

In step ST20 shown in FIG. 16, the cell placement module 51 shown in FIG. 13 places the sequential circuits 30a to 30d, the NAND circuits 31b and 31c, the NOT circuit 33b, and the AND circuit 32 in the cell array region 35, as shown in FIG. 15A. The cell array region 35 has a vertical length of VMAX and a horizontal length of HMAX.

In step ST21, the clock net generating module 52 generates a clock net 1a for the sequential circuits 30a to 30d so that the delay time to each sequential circuit can be the same, as shown in FIG. 15B.

In step ST23, the wiring route module 53 routes signal wirings that connect the sequential circuits 30a to 30d, the NAND circuits 31b and 31c, the NOT circuit 33b, and the AND circuit 32 to one another.

In step ST24, the wiring route module 53 routes the first virtual power line 4 connected to the sequential circuits 30a to 30d, the NAND circuits 31b and 31c, the NOT circuit 33b, and the AND circuit 32, and then terminates the circuit placement and route processing.

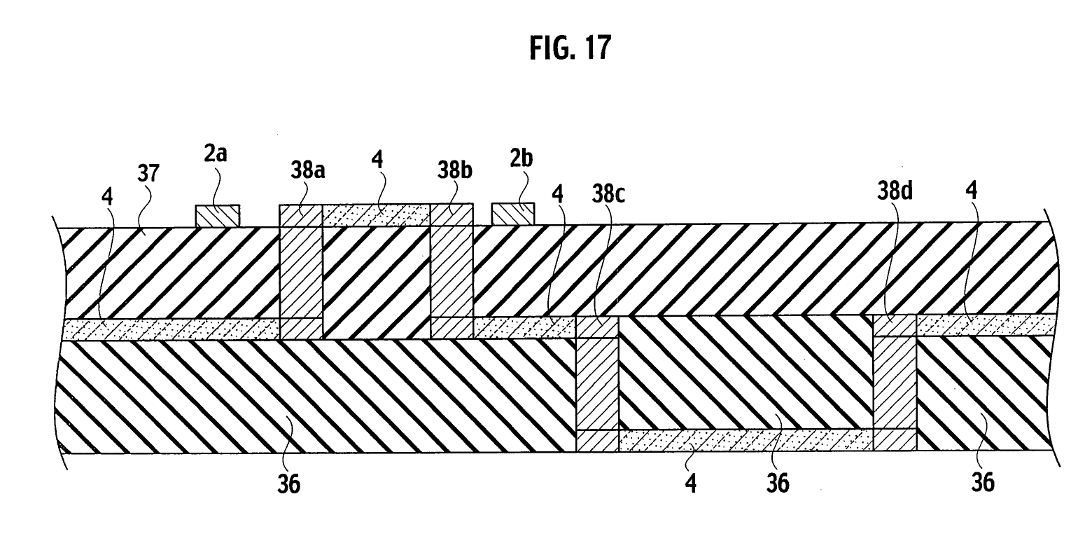

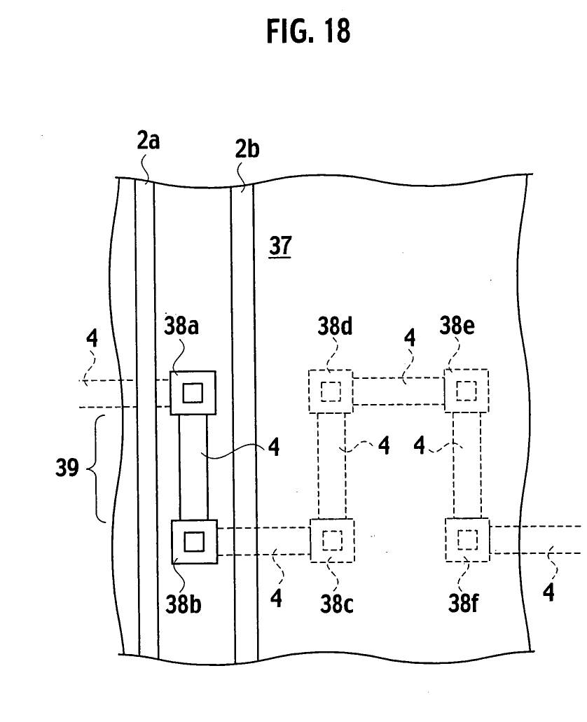

According to the semiconductor integrated circuit design method shown in the flowchart of FIG. 16, the first virtual power line 4 is routed last while avoiding the clock net 1a and other signal wirings. Therefore, the first virtual power line 4 is not long and the high possibility of crosstalk is avoided. FIG. 17 shows a cross section of the first virtual power line 4 having a small number of segments extending along signal wirings, while FIG. 18 shows top view thereof.

As shown in FIG. 17, the first virtual power line 4 is formed under a first insulator layer 36, between the first insulator layer 36 and a second insulator layer 37, and on the second insulator layer 37. The first virtual power line 4 formed by each layer is electrically connected by vias 38a to 38d.

An aggressing signal wiring 2a is formed on the second insulator layer 37 near via 38a while an aggressing signal wiring 2b is formed on the second insulator layer 37 near via 38b. However, since those aggressing signal wirings 2a and 2b do not extend along the first virtual power line 4, crosstalk does not occur.

As shown in FIG. 17, formation of the first virtual power line 4 with multi-layer interconnects allows shorter segments thereof routed in the same layer. As a result, route of the multi-layer first virtual power line 4 effectively prevents occurrence of crosstalk.

FIG. 18 is a plane view of the route of the first virtual power line 4 and aggressing signal wirings 2a and 2b shown in FIG. 17. Aggressing signal wirings 2a and 2b are routed to vertically extend in parallel with each other on the second insulator layer 37. Moreover, part of the first virtual power line 4 is sandwiched between the aggressing signal wirings 2a and 2b and arranged on the second insulator layer 37, via 38a is placed on one end of the first virtual power line 4, which is arranged on the second insulator layer 37, and via 38b is placed on the other end thereof.

The length of a crosstalk region 39 vertically extending on the second insulator layer 37 or the length of the part of the first virtual power line 4 extending in parallel with the aggressing signal wirings 2a and 2b on the second insulator layer 37 is shorter than the maximum virtual power line. In other words, since the length of the first virtual power line 4 extending along and adjacent to the aggressing signal wirings 2a and 2b is short, crosstalk can be effectively prevented.

The first virtual power line 4 routed between the first insulator layer 36 and the second insulator layer 37 is connected to a lower part of via 38a in a layer under the second insulator layer 37, and horizontally extends from a lower part of via 38b to an upper part of via 38c. The first virtual power line 4, routed under the first insulator layer 36, vertically extends from a lower part of via 38c to a lower part of via 38d. The first virtual power line 4 horizontally extends from an upper part of via 38d to an upper part of via 38e and vertically extends from a lower part of via 38e to a lower part of via 38f. Since the length of the virtual power line is short, occurrence of crosstalk can be effectively prevented.

### Third Embodiment

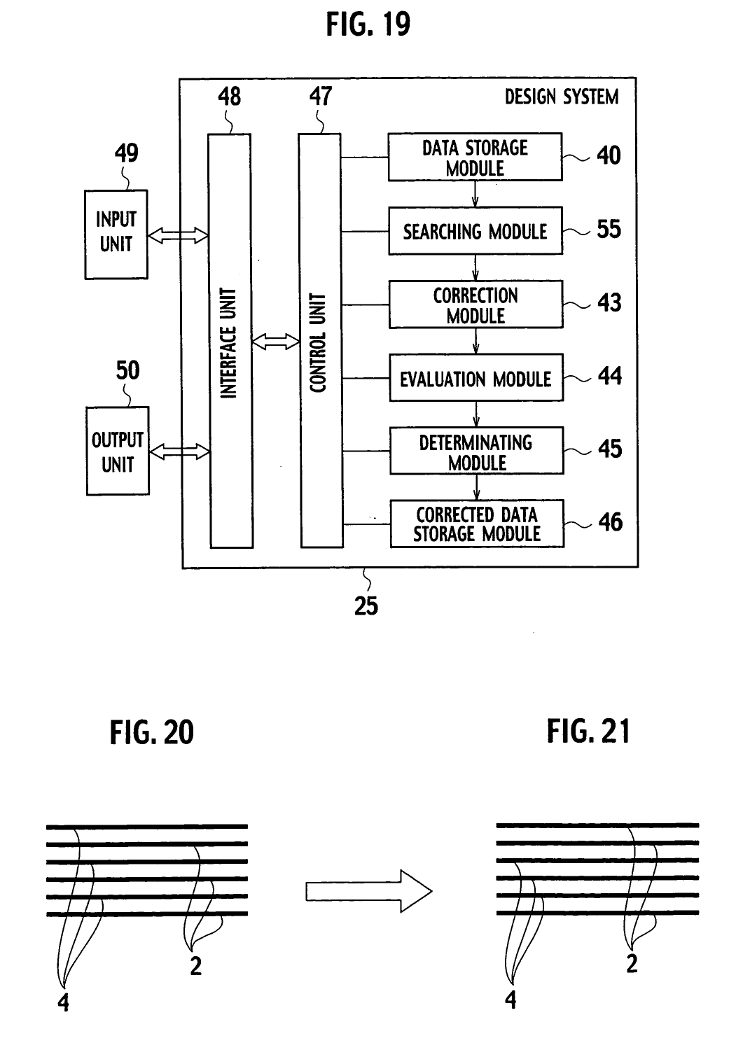

As shown in FIG. 19, the design system 25, according to a third embodiment of the present invention, includes a data storage module 40, which stores circuit data of a semiconductor integrated circuit, a searching module 55 connected to the data storage module 40 to search a wiring tracks in which a plurality of virtual power lines extend in the same direction, and a correction module 43, which reroutes a plurality of virtual power lines extending adjacent to one another in the same direction. Duplicate description of the data storage module 40, the evaluation module 44, the determinating module 45, the corrected data storage module 46, the control unit 47, the interface unit 48, the input unit 49, and the output unit 50, which are the same as those in the design system 25 in FIG. 10, is omitted.

The searching module 55 reads circuit data from the data storage module 40, and searches the wiring tracks in which a plurality of first virtual power lines 4 extend in the same direction, as shown in FIG. 20. In the wiring tracks shown in FIG. 20, signal wirings 2 and the first virtual power lines 4 are alternatively routed and extend in the same direction.

As shown in FIG. 21, the correction module 43 reroutes the plurality of first virtual power lines 4 to be adjacent to each other (hereafter, called ‘grouping route’). For example, a grouping route such that the fourth signal wiring 2 from the top in FIG. 20 is moved to the first position and that the first virtual power line 4 at the first position is then moved to the fourth position is effective because it is unnecessary to move the other wirings. Since the first virtual power lines 4 do not generate crosstalk, changes in signal delay of a logic circuit are not generated. While FIG. 20 shows an example of first virtual power lines 4 adjacent to and sandwiched between signal wirings 2 extending in the same direction, a grouping route of first virtual power lines 4 that are routed at a distance from the signal wirings 2 with other first virtual power lines 4 is possible.

The above description exemplifies exchange of two wirings; however, this does not limit the number of signal wirings 2 and number of first virtual power lines to be used in a grouping route. According to the semiconductor integrated circuit design method of the third embodiment, positions of all of the first virtual power lines 4 extending in the same direction may be changed according to circuit design.

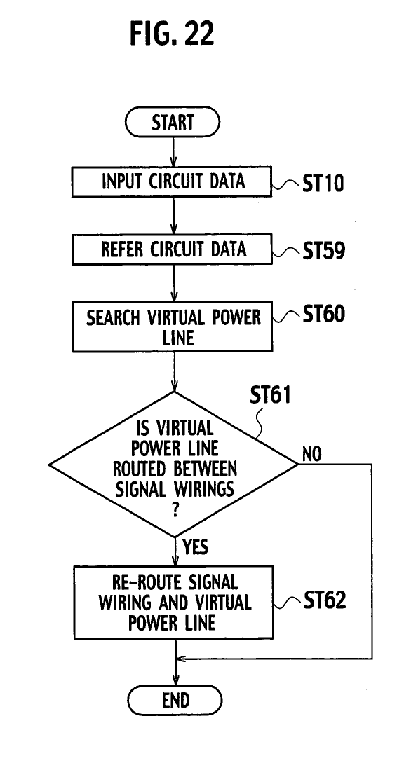

Referencing FIGS. 19 and 17 and a flowchart of FIG. 22, a semiconductor integrated circuit design method, according to the third embodiment, is described forthwith.

In step ST10 shown in FIG. 22, circuit data for the first virtual power lines 4 and the signal wirings 2 are received by the design system 25 shown in FIG. 19. The received circuit data is then stored in the data storage module 40.

In step ST59, the searching module 55 reads circuit data in the data storage module 40. Next, in step ST60, the searching module 55 searches the wiring tracks in which a plurality of first virtual power lines extend in the same direction.

In step ST61, if there is a region in which a first virtual power line 4 is sandwiched between signal wirings 2, the searching module 55 transfers circuit data of the wiring tracks in which a plurality of first virtual power lines 4 extend in the same direction to the correction module 43, and processing then proceeds to step ST62. Otherwise, if there is no tracks in which a first virtual power line 4 is sandwiched between signal wirings 2, the processing is terminated.

In step ST62, the correction module 43 reroutes a plurality of first virtual power lines 4 to extend in the same direction and be adjacent to each other, and processing is then terminated.

<Other Exemplary Circuits>

While the exemplary circuits described in the first to the third embodiment include transistors having differing threshold voltages, thereby achieving high speed operation and low power consumption, n-channel and p-channel transistors described in the following embodiments are not limited to multi-threshold CMOS transistors. And alternatively, they may be insulated gate transistors (MIS transistors) having a variety of gate insulators other than a silicon oxide (SiO₂). It is preferable to use MIS transistors made of materials having a larger dielectric constant, compared to a SiO₂ film for microscopic logic gates with wirings no wider than 100 nm.

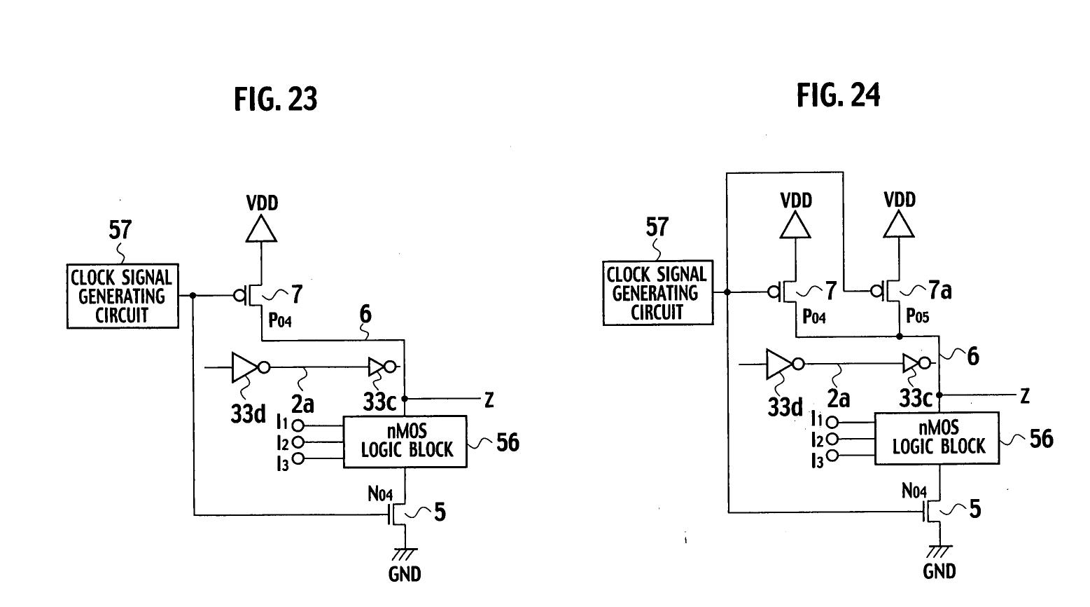

A semiconductor integrated circuit design system, according to an embodiment of the present invention, includes a dynamic logic gate of a first conductivity type MIS transistor using first conductivity type majority carriers and a second conductivity type MIS transistor having a second conductivity type majority carriers of opposite conductivity type to the first conductivity type, is explained forthwith using FIG. 23.

Here, when the first conductivity type of majority carriers is an electron, the first conductivity type MIS transistor using electrons as main current is an n-channel transistor. Since the majority carriers of the second conductivity type, which are of opposite conductivity type to the first conductivity type, are holes, the second MIS transistor is a p-channel transistor. On the other hand, when the first conductivity type majority carriers are holes, the first conductivity type MIS transistor is a p-channel transistor while the second conductivity type MIS transistor is an n-channel transistor.

A semiconductor integrated circuit in FIG. 23 is a logic circuit including a dynamic logic gate including a first conductivity type MIS transistor using first conductivity type majority carriers and a second conductivity type MIS transistor using second conductivity type majority carriers of opposite conductivity type to the first conductivity type. The dynamic logic gate includes an nMOS logic block 56 including first conductivity type MIS transistors, NOT circuits 33d and 33c including first conductivity type MIS transistors, MIS transistors 5 and 7, the second virtual power line 6, which connects the NMOS logic block 56 and the MIS transistor 7, and an aggressing signal wiring 2a. The MIS transistor 5 is a first conductivity type MIS transistor which provides the first conductivity type majority carriers to the nMOS logic block 56 from the first power line GND. The MIS transistor 7 is a second conductivity type MIS transistor, which moves the first conductivity type majority carriers from the NMOS logic block 56 to the second power line VDD. The aggressing signal wiring 2a is adjacent to and extends along the second virtual power line 6, and propagates a signal from the NOT circuit 33d to the NOT circuit 33c.

Changes in the potential of the aggressing signal wiring 2a, adjacent to and extending along the second virtual power line 6, decreases a potential provided to the NMOS logic block 56. This drop in potential is referred to as ‘IR (potential) drop’. Delay increase of the NMOS logic block occurs due to the IR drop, and may cause an operating fault.

Regarding the delay increase of the nMOS logic block 56 due to a drop in the potential of the second virtual power line 6, it is preferable to control the potential drop to be 10% or less according to a general design rule. Even a potential drop of 10% increases timing delay of the NMOS logic block 56 to some extent. Accordingly, crosstalk resulting in a potential drop of 10% or more is analyzed, and a network on the second power line VDD side is corrected to decrease the delay of the nMOS logic block 56.

In an exemplary circuit, when the output level of the NOT circuit 33d changes from ‘1’ to ‘0’ with the MIS transistor 7 being in a conductive state, crosstalk causes a decrease of the potential of the second virtual power line 6 adjacent to the aggressing signal wiring 2a. Thus, it causes an operating delay of the nMOS logic block 56.

The crosstalk simulator 41 (see FIG. 10) simulates crosstalk causing the IR drop of the second virtual power line 6. The analysis module 42 requests the correction module 43 to correct the semiconductor integrated circuit when the potential change including the IR drop of the second virtual power line 6 exceeds 10%.

As shown in FIG. 24, the correction module 43 places a MIS transistor 7a, or the second conductivity type MIS transistors, between the second virtual power line 6 and the second power line VDD. As a result, the first conductivity type majority carriers are taken out from the nMOS logic block within a short period of time.

In the dynamic logic gate shown in FIG. 24, the MIS transistors 7 and 7a are ‘precharge transistors’, and the MIS transistor 5 positioned on the first power line side is a ‘logic evaluation transistor (determining transistor)’. As shown in FIG. 24, other exemplary logic circuits include a clock generation circuit 57, which provides a lower potential while in a wait state.

Since the clock generation circuit 57 supplies a logic value of ‘0’ while in a wait state, the MIS transistors 7 and 7a turn on, the MIS transistor 5 turns off, and an output Z is a high level (an ‘H’ level).

According to the exemplary circuit shown in FIG. 24, crosstalk due to a falling signal of the NOT circuit 33d, routed along the aggressing signal wiring 2a, decreases the potential drop of the second virtual power line 6. As a result, a dynamic logic circuit, maintains the operating speed of the nMOS logic block 56, can be provided.

The circuits of the first to the third embodiment may be implemented by a MIS FET as a high threshold voltage MIS transistor, and a MIS static induction transistor (SIT) as a low threshold voltage MIS transistor with.

As well-known, the MIS SIT has an extremely short channel. In other words, the MIS SIT is defined as a device having a short channel, shortened to an extent allowing punch-through to occur between the source region and the drain region of the MIS FET. In the MIS SIT, a potential barrier established in the channel is controlled by a drain voltage and a gate voltage.

More specifically, the MIS SIT is a device having a specific potential profile between a source and a drain, and a potential at the saddle point in a two-dimensional potential profile established in a channel is controlled by a drain voltage and a gate voltage. Accordingly, since current-voltage characteristics of the MIS SIT show a similar exponential function to that for triode characteristics of a vacuum tube, a logic circuit can be implemented by a combination of a transistor (MIS SIT) having triode characteristics and a transistor (MIS FET) having pentode.

### Other Embodiments

While the exemplary dynamic logic gates according to the respective embodiments, each implemented by connecting the MIS transistor including a transistor having a high threshold voltage to the first power line GND and the second power line VDD and implementing the NAND circuit, the AND circuit, and the NOT circuit, have been described, the present invention is not limited to use of transistors having a low threshold voltage, and may alternatively use an nMOS logic block including n-channel MIS transistor.

Various modifications will become possible for those skilled in the art after receiving the teachings of the present disclosure without departing from the scope thereof.

1. A semiconductor integrated circuit comprising:
a logic circuit;
a first switching cell configured to connect a first power supply line with a first virtual power line positioned on the first power supply line side so as to drive the logic circuit; and
a second switching cell configured to connect a second power supply line with a second virtual power line positioned on the second power supply line side so as to drive the logic circuit;
wherein a time constant defined by the product of resistance and capacitance, which are measured between the first virtual power line and the first power supply line, is held to a constant value.

2. The semiconductor integrated circuit of claim 1, wherein the first virtual power line is divided into a plurality of virtual power lines.

3. The semiconductor integrated circuit of claim 1, wherein the first switching cell comprises a plurality of transistors having the same cell area, operating speed, and threshold voltage.

4. The semiconductor integrated circuit of claim 1, wherein the first switching cell and the second switching cell comprise transistors having a higher threshold voltage than a threshold voltage of transistors implementing the logic circuit.

5. The semiconductor integrated circuit of claim 1, wherein the first switching cell and the second switching cell are in a off state while the logic circuit is in a wait state.

6. The semiconductor integrated circuit of claim 1, wherein a second time constant defined by the product of resistance and capacitance which are measured between a second virtual power line and the second power supply line, is held to a constant value.

7. The semiconductor integrated circuit of claim 6, wherein the second virtual power line is divided into a plurality of virtual power lines.

8. The semiconductor integrated circuit of claim 6, wherein the second switching cell comprises a plurality of transistors having the same cell area, operating speed, and threshold voltage.

9. A computer implemented method for designing a semiconductor integrated circuit, comprising:
changing a signal level of an aggressing signal line adjacent to a virtual power line and extending along the virtual power line, and analyzing crosstalk along the virtual power line;
selecting the virtual power line and a transistor connected between the virtual power line and a power supply line when it is determined, based on the crosstalk analysis results, that crosstalk influences an operation of the semiconductor integrated circuit; and
correcting the semiconductor integrated circuit based on information of the virtual power line and the transistor.

10. The method of claim 9, wherein it is determined that the crosstalk influences the operation of the semiconductor integrated circuit when the potential change of the virtual power line exceeds an allowable threshold voltage, which is set so that the semiconductor integrated circuit operates normally.

11. The method of claim 10, wherein the allowable threshold is set based on increase in signal delay due to potential change of the virtual power line.

12. The method of claim 9, wherein correcting the semiconductor integrated circuit comprises dividing the virtual power line into a plurality of virtual power lines.

13. The method of claim 9, wherein correcting the semiconductor integrated circuit comprises expanding the gate width of the transistor.

14. The method of claim 9, wherein correcting the semiconductor integrated circuit comprises adding a transistor having the same cell area, operating speed, and threshold voltage as cell area, operating speed, and threshold voltage of the selected transistor, respectively, between the virtual power line and the power supply line.

15. The method of claim 9, further comprising evaluating the characteristics of the corrected semiconductor integrated circuit.

16. A computer implemented method for designing a semiconductor integrated circuit, comprising:
setting a maximum length constraint of a virtual power line driving a plurality of logic circuits and a plurality of sequential circuits;
placing the plurality of logic circuits and the plurality of sequential circuits in a cell array region set based on the maximum length constraint of the virtual power line;
generating a clock net for the plurality of sequential circuits; and
routing signal wiring to connect the plurality of logic circuits and the plurality of sequential circuits to one another, and the virtual power line connects the plurality of logic circuits and the plurality of sequential circuits, in the cell array region.

17. The method of claim 16, wherein the maximum length constraint of the virtual power line is set based on an increase in signal delay due to potential changes of the first virtual power line caused by crosstalk.

18. The method of claim 16, wherein the sum of the vertical length of the cell array region and the horizontal length thereof is equal to or less than the maximum length constraint of the virtual power line.

19. The method of claim 16, wherein routing the virtual power line comprises:
searching a wiring tracks in which a plurality of the virtual power lines extend in the same direction; and
routing the plurality of the virtual power lines to be adjacent to one another.

20. The method of claim 16, wherein the virtual power line is routed after route of the signal wiring in the cell array region.
